(19) United States
(12) Patent Application Publication
(10) Pub. No.: US 2011/0211668 A1
(43) Pub. Date: Sep. 1, 2011

(54) CONVERTER ELEMENT FOR A RADIATION DETECTOR

(75) Inventors: Roger Steadman Booker, Aachen (DE); Matthias Simon, Aachen (DE); Christoph Herrmann, Aachen (DE); Bernd Menser, Neu-Moresnet (BE); Jens Wiegert, Aachen (DE); Klaus Juergen Engel, Aachen (DE); Christian Baeumer, Dorsten-Rhade (DE); Oliver Muelhens, Aachen (DE)

(73) Assignee: KONINKLIJKE PHILIPS ELECTRONICS N.V., EINDHOVEN (NL)

(21) Appl. No.: 13/127,769

(22) PCT Filed: Nov. 9, 2009
(86) PCT No.: PCT/IB2009/054955

§ 371 Date: May 5, 2011

(30) Foreign Application Priority Data
Nov. 10, 2008 (EP) 08168762.6

(51) Int. Cl. G01N 23/04; G01T 1/16; G01T 1/24; H01L 31/18

(52) U.S. Cl. 378/19; 250/394; 250/370.13; 250/370.12; 250/370.01; 438/57; 257/E31.11

(57) ABSTRACT

The invention relates to converter element (100) for a radiation detector, particularly for a Spectral CT scanner. The converter element (100) comprises at least two conversion cells (131) that are at least partially separated from each other by intermediate separation walls (135) which affect the spreading of electrical signals generated by incident radiation (X). The conversion cells (131) may particularly consist of a crystal of CdTe and/or CdZnTe. Said crystal is preferably grown by e.g. vapor deposition between preformed separation walls.

### FIELD OF THE INVENTION

The invention relates to a converter element for a radiation detector, a radiation detector comprising such a converter element, an imaging system comprising such a radiation detector, and a method for manufacturing such converter elements.

### BACKGROUND OF THE INVENTION

The US 2007/03006 A1 discloses an X-ray detector for a Spectral CT (Computed Tomography) scanner in which incident X-ray photons are counted and classified with respect to their energy. The detector comprises a conversion material that absorbs incident X-ray photons and electrodes for the detection of the resulting electrical signals. To cope with high count rates, an array of single anodes is provided on a crystal block of conversion material to reduce the effective size of the pixels. A problem of this detector is however, that the charge clouds that are generated by incident X-ray photons can be spread over different pixels, thus deteriorating the spatial and/or spectral resolution.

### SUMMARY OF THE INVENTION

Based on this situation it was an object of the present invention to provide means for improving the accuracy of radiation detection, particularly in connection with radiation detectors for Spectral CT.

This object is achieved by a converter element according to claim 1, a radiation detector according to claim 11, an imaging system according to claim 12, and a method according to claim 13. Preferred embodiments are disclosed in the dependent claims.

According to its first aspect, the invention relates to a converter element for a radiation detector that comprises the following components:

a) At least two units that will be called “conversion cells” in the following and that consist of a conversion material for converting incident electromagnetic radiation into electrical signals. The “conversion cells” will in a radiation detector typically be operated such that their signal corresponds to one picture element (“pixel”) of an image generated from incident radiation with said detector. The detected electromagnetic radiation may particularly comprise X-rays or γ-rays, and the electrical signal generated by a photon of the radiation will usually correspond to a cloud of charges (e.g. electron-hole pairs) that are mobile in the conversion material.
b) At least one “separation wall” that is disposed between the aforementioned conversion cells and materially bonded to them. As usual, the term “materially bonded”, which is synonymous to “inter-materially joined”, “fused”, or “in material fit”, shall denote a junction between two materials on a molecular level. Such a material bonding can for example be achieved by gluing, soldering, welding, or crystal growth of one material on or around the other. Preferably, the material of the separation wall is directly (i.e. without any intermediate material like glue) materially bonded to the conversion cells.

It should be noted that the separation wall may in principle have any shape and dimension, though it will typically be formed like a sheet or flat plate. Several such plates will then by convention be counted as different “separation walls”, though they might as well conceptually be considered as one (more intricately shaped) separation wall.

In converter elements for Spectral CT known in the state of the art (e.g. US 2007/03006 A1), unique blocks of conversion material are provided that are functionally subdivided into a plurality of cells by an electrode array disposed on them. Charge clouds generated by incident photons can however freely spread in such blocks and thus reach pixel electrodes of other cells than those they were generated in. In contrast to this, the spreading of electrical signals can be controlled by the separation wall between two conversion cells in the converter element of the present invention. With an appropriate design of the separation wall, it is particularly possible to restrict a charge cloud to the conversion cell it was generated in, even if said cell has only a small volume. Thus a substantial improvement of the accuracy and spatial/spectral resolution of the converter element can be achieved.

The conversion material that is used for the conversion cells may particularly comprise CdTe and/or CdZnTe (“CZT”), which materials have favorable conversion characteristics that make them suitable for an application in e.g. Spectral CT based on photo counting. On the other hand, these conversion materials are very brittle, making their mechanical processing difficult and preventing for example the cutting of small pieces. Due to the material bonding between the conversion cells and the separation wall, the converter element of the present invention provides a stable structure even for such brittle conversion materials. Other possible direct conversion materials for the conversion cells are e.g. Si and GaAs.

In general, the conversion cells may have any shape and size. In a preferred embodiment, the conversion cells will however have a substantially cylindrical or cuboid form with an area (measured perpendicularly to the longitudinal axis) of about 0.01×0.01 mm² to 1×1 mm², preferably of about 0.05×0.05 mm² to about 0.3×0.3 mm². In another preferred embodiment, the conversion cells may have a more or less flat geometry with a thickness of less than about 1 mm, preferably less than about 0.05 mm.

Conversion cells with these dimensions are for example suited for a radiation detector in Spectral CT. If consisting of the aforementioned brittle conversion materials, such small conversion cells could hardly be fabricated by cutting or sawing.

At least one conversion cell of the converter element may completely be separated from neighboring conversion cells by one or more separation walls. In this case the influence of the separation wall(s) on the electrical signals generated in said conversion cell is maximized and extends over the whole pixel volume.

In another embodiment of the converter element, the two conversion cells that are materially bonded to the separation wall may additionally be in direct contact to each other. Such a direct contact of the conversion cells may advantageously provide additional mechanical stability via e.g. a material fusion of the conversion cells.

The above description comprises converter elements with just two conversion cells separated by one separation wall. In a preferred embodiment, the converter element will however comprise a plurality of (more than two) conversion cells with a plurality of separation walls between them, thus establishing a one- or two-dimensional arrangement.

The separation wall may be electrically conductive and e.g. comprise a metallic material. In a preferred embodiment, the separation wall is however electrically isolating. This has the advantage that the wall can prevent the transition of electrical charges into neighboring conversion cells while simultaneously preserving said charges for a detection in their conversion cell of origin. Particularly suited materials for the separation wall comprise ceramic materials and semiconductors like silicon (Si), particularly when coated with an electrical isolation (e.g. an oxide of the material).

To allow for the detection and evaluation of the electrical signals generated in the conversion cells, the converter element may comprise first electrodes that are individually connected to the conversion cells on a first side of said cells. The first electrodes may particularly be operated as anodes at which electrons that have been lifted in the conversion cell into the conduction band can be collected and detected.

To generate a well-defined electrical field in the conversion cells, the converter element may advantageously be provided with a second electrode to which all conversion cells are commonly connected on a second side of the cells. This second electrode will usually be operated as a cathode.

The invention further relates to a radiation detector comprising a converter element of the kind described above and additional components, for example readout circuits for detecting, processing and evaluating the electrical signals generated in the converter element.

Furthermore, the invention relates to an imaging system, for example a Spectral CT scanner, that comprises a radiation detector of the aforementioned kind and additional components, e.g. a data processing unit and a radiation source.

Finally, the invention relates to a method for manufacturing a converter element for a radiation detector, particularly a converter element of the kind described above. The method comprises the following steps:

a) Providing a seed material which is chosen such that a crystal of the conversion material mentioned below can grow on it.
b) Providing at least one preformed separation wall of a first material on the seed material.
c) Growing a crystal of conversion material on the seed material such that the separation wall is at least partially embedded in the conversion material, wherein the conversion material is adapted to convert electromagnetic radiation into electrical signals. The crystal growth may for example be done inside the separation walls out of a melt of conversion material, or by physical vapor deposition (PVD).

The method allows to produce a converter element of the kind described above. Therefore, reference is made to the preceding description for more information on the details, advantages and improvements of that method.

There are different methods to grow a crystal of conversion material on a seed material. According to a preferred embodiment, the crystal growth is achieved by vapor deposition of the conversion material on the seed material.

The first material from which the preformed separation wall is constructed may optionally only be a temporary placeholder. In this case it is preferred that the first material of the preformed separation wall is at least partially removed after the crystal of conversion material has been grown. The resulting gaps may then be left void, or the removed first material is at least partially replaced by a second material which becomes (part of) the final separation wall. The second material of the separation wall can for example be a material that would not sustain the previous process of crystal growth.

### BRIEF DESCRIPTION OF THE DRAWINGS

These and other aspects of the invention will be apparent from and elucidated with reference to the embodiment(s) described hereinafter. These embodiments will be described by way of example with the help of the accompanying drawings in which:

FIG. 1 schematically illustrates a CT system as an example of an imaging system according to the present invention;

FIG. 2 shows a first embodiment of a converter element according to the present invention with separation walls completely surrounding the conversion cells;

FIG. 3 shows a second embodiment of a converter element according to the present invention with separation walls that extend only partially into the conversion material;

FIG. 4 schematically illustrates an apparatus for manufacturing a converter element according to the present invention;

FIG. 5 shows preformed separation walls on a seed material.

### DESCRIPTION OF PREFERRED EMBODIMENTS

Like reference numbers or numbers differing by integer multiples of 100 refer in the Figures to identical or similar components.

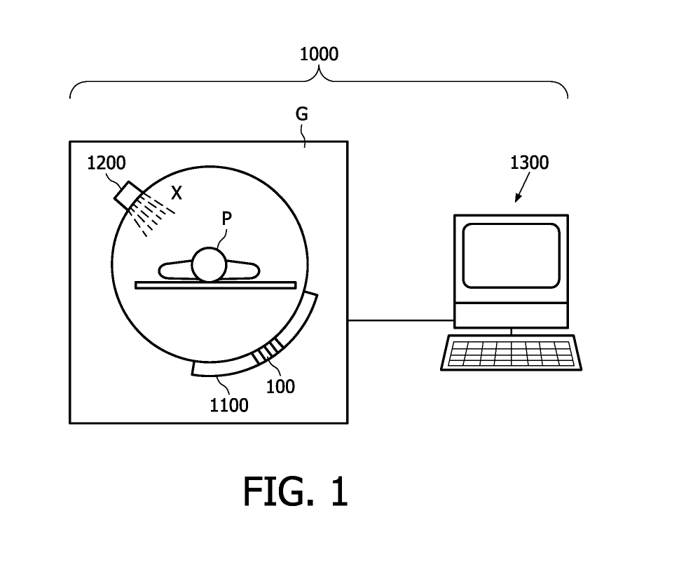

The following description will refer to the example of a Spectral CT (Computed Tomography) scanner 1000 as it is schematically shown in FIG. 1, though the present invention is not limited to this application. The Spectral CT scanner 1000 comprises a gantry G in which an X-ray source 1200 and an X-ray detector 1100 are mounted opposite to each other such that they can rotate around a patient P lying on a table in the middle of the gantry. The detector 1100 and the radiation source 1200 are connected to a control unit 1300, for example a workstation with input means (keyboard) and output means (monitor).

Spectral CT has a high diagnostic potential as spectral information contained in the poly-chromatic X-ray beam generated by an X-ray source and passing a scanned object is used to provide new and diagnostically critical information. The enabling technology for Spectral CT imaging systems is a detector, which can provide a sufficiently accurate estimate of the flux and the energy spectrum of the photons hitting the detector behind the scanned object. Since for image reconstruction reasons the detector is also exposed to the direct beam, the photon count rates in a detector pixel irradiated by the direct beam are enormous (approximately 10⁹ photons per mm² and second, i.e. 1000 Mcps). In conventional hardware, a detector pixel will be saturated at a count rate of about 10 Mcps.

An approach to deal with these high counting rates is to sub-structure the sensor part of the detector, in which sensor an X-ray photon interacts and generates a charge pulse, which is further evaluated by the readout electronics. Two-dimensional sub-structuring into small conversion cells (e.g. with an area of 300 μm×300 μm) lying next to each other in a plane perpendicular to the beam direction can be considered as well as a three-dimensional sub-structuring into several different sensor layers stacked in beam direction. In this approach, each sub-pixel in a sensor layer has its own energy-resolving readout electronics channel with sub-channels for each energy.

Smaller pixels for a given detector thickness (measured in beam direction) typically deliver also a better spectral response due to the so-called “small-pixel effect”. However, charge sharing becomes a dominant crosstalk phenomenon across neighboring pixels and sets the lower limit of pixelation as it decreases spectral performance. This is due to the fact that an X-ray interaction in the bulk of the conversion material generates an electron cloud (holes are not considered here for simplicity) which drifts along the flux lines of the electric field (in opposite direction to said field) that is established by the potential between a common cathode and the anodes. The electron cloud has finite dimensions and it expands (via diffusion processes and Coulomb repulsion) as it drifts towards the anode. Eventually, some of the charges will drift to neighboring pixels and thus distribute the total charge to several pixels, which makes it difficult to deduce the original photon energy.

To address these problems, it is proposed herein to include a separation material (e.g. an insulator) in between pixels, thus minimizing the effect of charge sharing significantly. However, as CdTe and CdZnTe are among the most promising direct conversion materials for Spectral CT and as these are very brittle materials, pixel structuring is a not a trivial task.

One possible work around is to grow the crystal already confined in a pixel structure (one or two-dimensional). Crystal growth methods described in literature (cf. Pelliciari, B; et al., “A new growth method for CdTe—a breakthrough towards large areas”, Journal of Crystal Growth 275 (2005) pp. 99-105; Mullins J. T., et al., “Crystal growth of large-diameter bulk CdTe on GaAs wafer seed plates”, Journal of Crystal Growth 310 (2008) pp. 2058-2061, Mullins J. T., et al., “Vapor-Phase Growth of Bulk Crystals of Cadmium Telluride and Cadmium Zinc Telluride on Gallium Arsenide Seeds”, Journal of Electronic Material 37 (2008), 1460-1464) can be adapted to a setup in which a crystal is grown in a predefined structure.

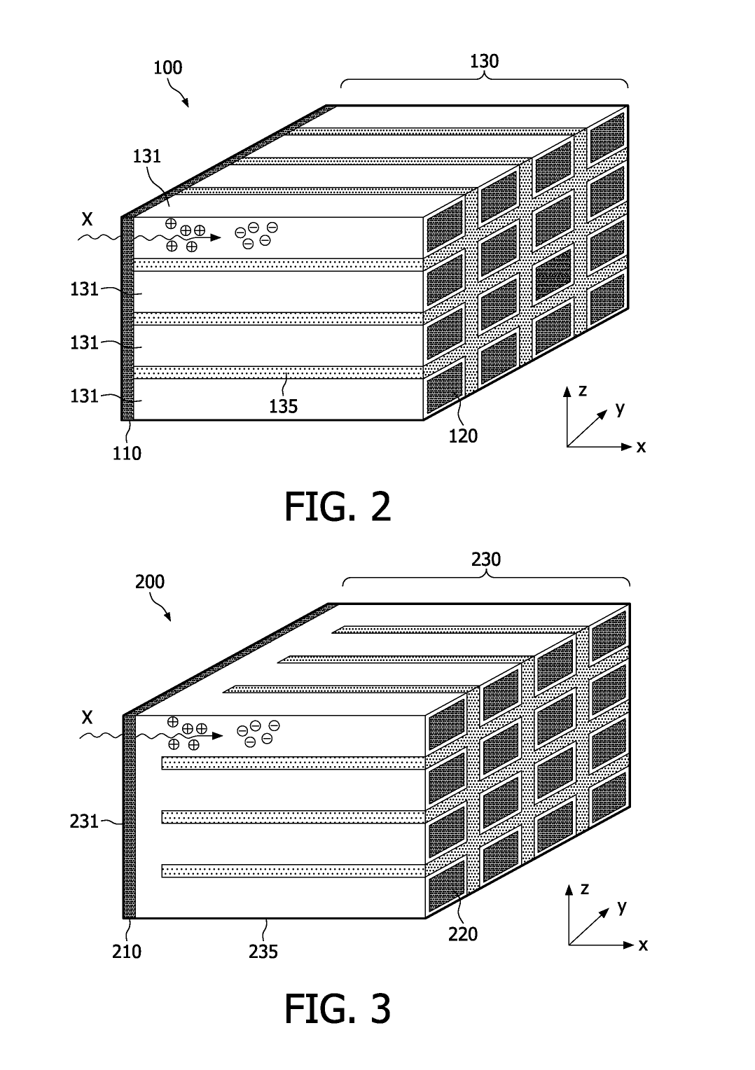

FIG. 2 illustrates a first embodiment of a converter element 100 with a converter block 130 that is structured into a two-dimensional array of cuboid-shaped conversion cells 131 separated from each other by separation walls 135. The size of the shown converter element 100 is typically 1.5×1.5×3 mm³, and a radiation detector comprises a large number of such elements in a two-dimensional arrangement in the xy-plane (such a larger detector would typically be a continuous device produced as wafer). The conversion cells 131 carry on their front side individually addressable anodes 120, wherein the electronics contacting said anodes for reading out and processing the detected signals are not shown for simplicity. On the back side of the converter block 130, a common cathode 110 is placed that covers the back side of all conversion cells 131.

When an X-ray photon generates a cloud of charges (electron-hole pairs) in the conduction band of the conversion material, for example in the top left conversion cell 131 of FIG. 2, the spreading of this cloud is limited by the separation walls 135 to the very conversion cell it was generated in. In this way the spatial and spectral resolution of the converter element 100 can considerably be improved while simultaneously reducing the effective pixel size such that the occurring maximal count rates can be coped with.

It should be noted that, though the Figures show an incidence of the X-ray photons along the x-direction, the detector can be used for any other direction of photon incidence, particularly a perpendicular incidence along the positive or negative x, y or z-direction.

FIG. 3 shows an alternative embodiment of a converter element 200 with a conversion block 230, a common cathode 210, and individual anodes 220. In contrast to the previous embodiment, the separation walls 235 extend only partially (in x-direction) into the converter block 230. The conversion cells 231 are therefore in contact to each other (i.e. fused) at the back side near the common cathode.

The invention also comprises a method to grow e.g. Cd(Zn)Te crystals embedded in a pre-defined pixel structure.

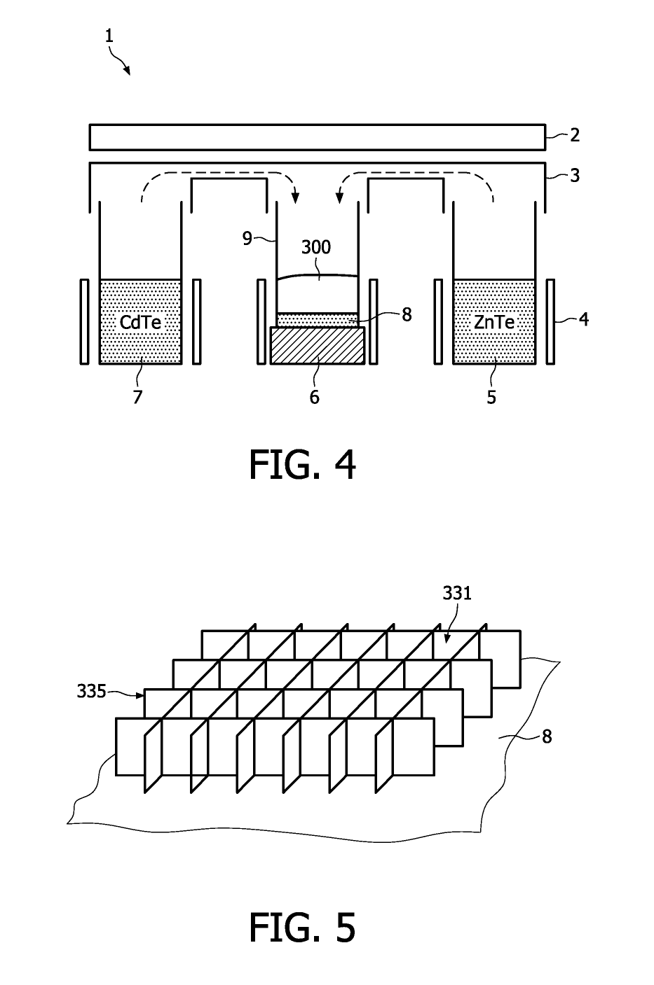

FIG. 4 shows a corresponding apparatus 1 for manufacturing a converter element 300 according to the present invention by growing a crystal (in this case CdTe or CdZnTe) from a GaAs seed wafer 8 with the method of Multi-tube Physically Vapor Transport (MTPVT, cf. Mullins et al., above).

The apparatus 1 is disposed in a vacuum ambient and comprises two tubes 5, 7 that are filled with ZnTe and CdTe, respectively. In a central tube 9, to which the aforementioned tubes 5, 7 are connected via a crossmember 3, a converter element 300 is grown on a seed material 8 that is placed upon a pedestal 6. The crossmember and the tubes can be heated by heaters 2, 4.

As shown in FIG. 5 in more detail, a pre-pixelated separation wall structure 335 is deposited on top of the seed wafer 8 at the beginning of the manufacturing process. The pre-defined structure may consist of one- or two-dimensional walls, wherein FIG. 5 shows an example of a two-dimensional grid with holes 331 for the conversion cells. The conversion material is then grown in these holes during the vapor deposition process.

After crystal growth, a post-processing step may be necessary to dice the resulting ingots to the desired detector geometry. Grinding and polishing can be used to finish the converter element according to e.g. FIG. 2 or 3.

The pre-defined separation wall structure can basically be made of any material which withstands the temperature cycle of the crystal growth process. Examples of suitable materials are Si (preferably with oxidized walls) or ceramics.

In an alternative embodiment, the preformed separation walls 335 of FIG. 5 can consist of a precursor material that is used as a placeholder for the final separation walls during crystal growth. After the conversion material has been grown, this precursor material can be removed, for example by etching. In the resulting voids, any other material compatible with the mechanical/chemical specifications of the crystal can then be deposited to constitute the final separation walls.

The single-pixel structuring of the described radiation detectors allows to harvest all the benefits of having small pixels while avoiding performance degradation due to charge sharing. A radiation detector comprising converter elements of the kind described above is of particular benefit when used in direct converters for Spectral CT. However, any other application or material which benefits from pre-defined pixel structures could make use of the invention, too.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A converter element (100, 200, 300) for a radiation detector (1100), comprising
a) at least two conversion cells (131, 231, 331) consisting of a conversion material for converting incident electromagnetic radiation (X) into electrical signals;
b) at least one separation wall (135, 235, 335) that is disposed between the conversion cells and materially bonded to them.

2. The converter element (100, 200, 300) according to claim 1,
characterized in that the conversion material comprises CdTe, CdZnTe, Si and/or GaAs.

3. The converter element (100, 200, 300) according to claim 1,
characterized in that the conversion cells (131, 231, 331) have a substantially cylindrical or cuboid form with a basic area of about 0.01 mm² to 1 mm² and/or with a thickness of less than 1 mm.

4. The converter element (100) according to claim 1,
characterized in that at least one conversion cell (131) is completely separated from neighboring conversion cells by separation walls (135).

5. The converter element (200) according to claim 1,
characterized in that the two conversion cells (231) are partially in direct contact to each other.

6. The converter element (100, 200, 300) according to claim 1,
characterized in that it comprises a one- or a two-dimensional structure of a plurality of conversion cells (131, 231, 331) with separation walls (135, 235, 335) between them.

7. The converter element (100, 200, 300) according to claim 1,
characterized in that the separation wall (135, 235, 335) is electrically isolating.

8. The converter element (100, 200, 300) according to claim 1,
characterized in that the material of the separation wall (135, 235, 335) comprises a semiconductor like Si, particularly with an oxidized surface, or a ceramic material.

9. The converter element (100, 200, 300) according to claim 1,
characterized in that the conversion cells (131, 231, 331) are individually connected to first electrodes (120, 220) on a first side.

10. The converter element (100, 200, 300) according to claim 1,
characterized in that the conversion cells (131, 231, 331) are connected to a common second electrode (110, 210) on a second side.

11. A radiation detector (1100), comprising a converter element (100, 200, 300) according to claim 1.

12. An imaging system (1000), particularly a Spectral CT scanner, comprising a radiation detector (1100) according to claim 11.

13. A method for manufacturing a converter element (100, 200, 300) for a radiation detector (1100), comprising the following steps:
a) providing a seed material (8);
b) providing at least one preformed separation wall (335) on the seed material;
c) growing a crystal of a conversion material, which can convert electromagnetic radiation (X) into electrical signals, on the seed material such that the separation wall (335) is at least partially embedded.

14. The method according to claim 13,
characterized in that the crystal of the conversion material is grown on the seed material (8) by vapor deposition.

15. The method according to claim 13,
characterized in that the original material of the separation wall (335) is at least partially removed after crystal growth and preferably at least partially replaced by another material
